(19) United States
(12) Patent Application Publication
(10) Pub. No.: US 2024/0063001 A1
(43) Pub. Date: Feb. 22, 2024

(54) METHODS AND SYSTEMS FOR ENDPOINT DETECTION IN FORELINE OF CHAMBER CLEAN AND FORELINE CLEAN PROCESSES

(71) Applicant: MKS Instruments, Inc., Andover, MA (US)

(72) Inventors: Hongke Ye, Andover, MA (US); Gordon Hill, Arlington, MA (US)

(21) Appl. No.: 18/449,488

(22) Filed: Aug. 14, 2023

Related U.S. Application Data
(60) Provisional application No. 63/371,706, filed on Aug. 17, 2022.

(51) Int. Cl. H01J 37/32; C23C 16/44

(52) U.S. Cl. CPC H01J 37/32862; H01J 37/32963; C23C 16/4405

(57) ABSTRACT

Systems and methods of monitoring a cleaning process for a deposition chamber are provided. A chamber cleaning source is activated to supply a cleaning agent to a deposition chamber and a foreline cleaning source disposed downstream of the deposition is activated to supply the cleaning agent to a foreline. The transmission recovery of an optical sensor disposed in the foreline is monitored. The optical sensor is disposed in the foreline at a location downstream of the foreline cleaning source. At least one of a foreline clean endpoint and a chamber clean endpoint is detected based on the monitored transmission recovery.

### RELATED APPLICATION

This application claims the benefit of U.S. Provisional Application No. 63/371,706, filed on Aug. 17, 2022. The entire teachings of the above application is incorporated herein by reference.

### BACKGROUND

Deposition processes, including chemical vapor deposition (CVD) processes, are commonly used in the manufacturing of semiconductor devices. For example, in a typical CVD process, reactant gases are introduced into a wafer processing chamber and directed to a heated substrate to induce controlled chemical reactions, which result in the deposition of a thin film on the surface of the substrate. During the deposition process, chamber pressure is precisely controlled by one or more mechanical devices, such as vacuum valves, connected downstream from the wafer processing chamber. For example, an isolation valve is typically connected directly to the exhaust gas port of the wafer processing chamber, a throttle valve is situated downstream from the isolation valve, and a vacuum pump is located further downstream from both of the isolation and throttle valves. The plumbing between the wafer processing chamber and the vacuum pump (e.g., the pipelines and valves) is generally referred to as a foreline, a roughing line or a vacuum pumping line.

During a wafer deposition process, unwanted material produced from the reactant gases can be deposited along the vacuum pumping line as the reactant gases are pumped out from the processing chamber through the pumping line. Accumulation of the unwanted material in the vacuum pumping line can produce a host of problems, including clogging the pumping line and other downstream equipment, interfering with normal operation of the associated vacuum pump, reducing the vacuum pump's useful life, and contaminating processing steps in the processing chamber.

Existing systems and methods are available for cleaning the wafer processing chamber and/or the vacuum pumping line. For example, an inline plasma source for cleaning at least a portion of a vacuum pumping line is described by U.S. Pat. No. 10,535,506, assigned to MKS Instruments, Inc. of Andover, Mass., the contents of which are hereby incorporated herein by reference. Plasma sources may also be in connection with the chamber to provide for a chamber cleaning process.

Existing methods for detecting an endpoint of a cleaning process are also known. For example, methods of determining endpoints of a cleaning process applied to a wafer processing chamber and a pumping line based on monitoring performed by a downstream endpoint detector coupled to the pumping line are described in U.S. Pub. No. 2022/0048081, assigned to MKS Instruments, Inc. of Andover, Mass., the contents of which are hereby incorporated herein by reference.

There exists a need for methods and systems capable of providing more consistent and accurate detection of endpoints associated with chamber and foreline cleaning processes.

### SUMMARY

Methods and systems for monitoring a cleaning process for a deposition chamber are provided that can result in more accurate and consistent indications of chamber and/or foreline clean endpoints. The provided methods and systems can overcome problems relating to the use of optical-based (e.g., IR-based) endpoint detection sensors in chamber and foreline cleaning processes.

A method of monitoring a cleaning process for a deposition chamber includes activating a chamber cleaning source to supply a cleaning agent to a deposition chamber and activating a foreline cleaning source disposed downstream of the deposition chamber to supply the cleaning agent to a foreline. The method further includes monitoring transmission recovery of an optical sensor disposed in the foreline at a location downstream of the foreline cleaning source and detecting at least one of a foreline clean endpoint and a chamber clean endpoint based on the monitored transmission recovery.

The method can be employed with the optical sensor being disposed at varying distances from the foreline cleaning source. For example, a spacing between the foreline cleaning source and the optical sensor can be selected to provide for a targeted rate of transmission recovery. Optionally, a spacing between the foreline cleaning source and the optical sensor is selected to provide for detection of the foreline clean endpoint at a location in the foreline associated with a system component located downstream of the deposition chamber. The system component can be a component of interest, such as a pump, for which an accurate determination of cleanliness can be desirable.

In an example implementation, a foreline clean endpoint can be detected based on a transmission level of the optical sensor reaching a threshold recovery value, and a concentration of a cleaning byproduct in the foreline can thereafter be monitored with the sensor. A chamber clean endpoint can be detected based on the monitored concentration of the cleaning byproduct reaching a threshold value. Alternatively, a chamber clean endpoint can be detected based on a transmission recovery rate and a rate of change of a monitored concentration of a cleaning byproduct, the transmission recovery rate being calibrated to a rate of change of concentration of a cleaning byproduct in the foreline. For example, a difference between the transmission recovery rate and the rate of change of the monitored concentration of cleaning byproduct can reach a threshold value indicating that a chamber clean endpoint has been reached. A foreline clean endpoint can be detected based on a transmission recovery rate reaching a threshold value, the transmission recovery rate being calibrated to a rate of change of concentration of a cleaning byproduct in the foreline.

The method can include monitoring an optical signal having a wavelength absorbed by the cleaning byproduct. The monitoring of the concentration of the cleaning byproduct can be based on at least one of tunable filter spectroscopy (TFS), non-dispersive infrared (NDIR) analysis, residual gas analysis (RGA), Fourier transform infrared spectroscopy (FTIR), and optical emission spectroscopy (OES). The cleaning byproduct can be a fluorinated, chlorinated, or oxygen-containing gas formed from reaction of the cleaning agent with a deposition material, such as, for example, SiF₄, and oxidized gas, such as CO or CO₂.

Monitoring transmission recovery of the optical sensor can include monitoring an optical signal having a wavelength not absorbed by a cleaning byproduct generated during cleaning with the cleaning agent. A concentration of a cleaning byproduct present in at least one of the foreline and the chamber can be based on the monitored transmission recovery and the monitored optical signal having the wavelength absorbed by the cleaning byproduct.

Activation of the foreline cleaning source can occur concurrently with activation of the chamber cleaning source. The optical sensor can include optical windows disposed at an inner surface of the foreline. The optical sensor can be disposed at an outlet of the foreline cleaning source and can, optionally, be integral with the foreline cleaning source.

A system for monitoring cleaning of a deposition chamber includes a chamber cleaning source configured to supply a cleaning agent to a deposition chamber and a foreline cleaning source disposed downstream of the deposition chamber and configured to supply the cleaning agent to a foreline. The system further includes an optical sensor disposed in the foreline at a location downstream of the foreline cleaning source and electronics configured to monitor transmission recovery of the optical source and detect at least one of a foreline clean endpoint and a chamber clean endpoint based on the monitored transmission recovery

The electronics can be configured to detect the foreline clean endpoint based on a transmission level of the optical sensor reaching a threshold recovery value. The electronics can be configured monitor a concentration of a cleaning byproduct in the foreline with the sensor and, optionally, detect the chamber clean endpoint based on the monitored concentration of the cleaning byproduct reaching a threshold value. Alternatively, the electronics can be configured to detect the chamber clean endpoint based on a transmission recovery rate and a rate of change of a monitored concentration of the cleaning byproduct. For example, the chamber endpoint can be detected based on a difference between the transmission recovery rate and the rate of change of the monitored concentration of cleaning by product reaching a threshold value. The transmission recovery rate can be calibrated to a rate of change of concentration of a cleaning byproduct in the foreline. The electronics can be configured to detect the foreline clean endpoint based on a transmission recovery rate reaching a threshold value, the transmission recovery rate being calibrated to a rate of change of concentration of a cleaning byproduct in the foreline.

The optical sensor can include optical windows disposed at an inner surface of the foreline. The optical sensor can be disposed at varying distances from the foreline cleaning source. For example, the optical sensor can be disposed in the foreline at a distance of about 5 cm to about 15 m downstream from the foreline cleaning source. The optical sensor can be disposed at an outlet of the foreline cleaning source and, optionally, can be integral with the foreline cleaning source. Where the optical sensor is disposed in the foreline at a distance of, for example, less than about 50 cm, or less than about 1 m, the electronics can be configured to detect a chamber clean endpoint based on the monitored concentration of the cleaning byproduct reaching a threshold value. Where the optical sensor is disposed in the foreline at a distance of, for example, greater than about 1 m, greater than about 2 m, or about 1 m to about 15 m, the electronics can be configured to detect a chamber clean end point based on both a transmission recovery rate and a rate of change of a monitored concentration of the cleaning byproduct.

A method for monitoring cleanliness of a foreline in a deposition system includes, with an optical sensor disposed in a foreline at a location downstream of a deposition chamber, measuring transmission of an optical signal through the foreline, the measured transmission indicative of an amount of deposited material present in the foreline.

Measuring transmission through the foreline can include measuring attenuation of the optical signal, the measured attenuation indicative of a thickness of a film of the deposited material at an inner surface of the foreline. Alternatively, or in addition, the optical sensor can include a detector array, and measuring transmission through the foreline can include measuring scattering of the optical signal. The method can further include monitoring a concentration of a cleaning byproduct in the foreline with the optical sensor.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 is a schematic of a prior-art chemical vapor deposition (CVD) system with chamber and foreline cleaning sources and an endpoint detector.

FIG. 2 is a schematic of a CVD system with chamber and foreline cleaning sources and including an endpoint detector disposed in the foreline.

FIG. 3 is a schematic of a CVD system with chamber and foreline cleaning sources and including an endpoint detector disposed at an outlet of the foreline cleaning source.

FIG. 4 is a graph illustrating an example output of an endpoint detector where the endpoint detector is positioned in the foreline close to a foreline cleaning source. The graph units are arbitrary units (a.u.).

FIG. 5A is a graph illustrating an example output of an endpoint detector where the endpoint detector is positioned in the foreline at a distance away from the foreline cleaning source. The graph units are arbitrary units (a.u.).

FIG. 5B is an expanded view of a portion of the graph of FIG. 5B illustrating detection of a chamber clean endpoint and a foreline clean endpoint based on transmission recovery of the endpoint detector. The graph units are arbitrary units (a.u.).

FIG. 6 is a schematic of a CVD system with a coating of deposited material at an inner surface of a foreline.

FIG. 7 is a schematic of example of a CVD system with a foreline cleaning source disposed in a chamber and an endpoint detection system.

FIG. 8 is a schematic of an example of a CVD system with a remote plasma source and an endpoint detection system.

### DETAILED DESCRIPTION

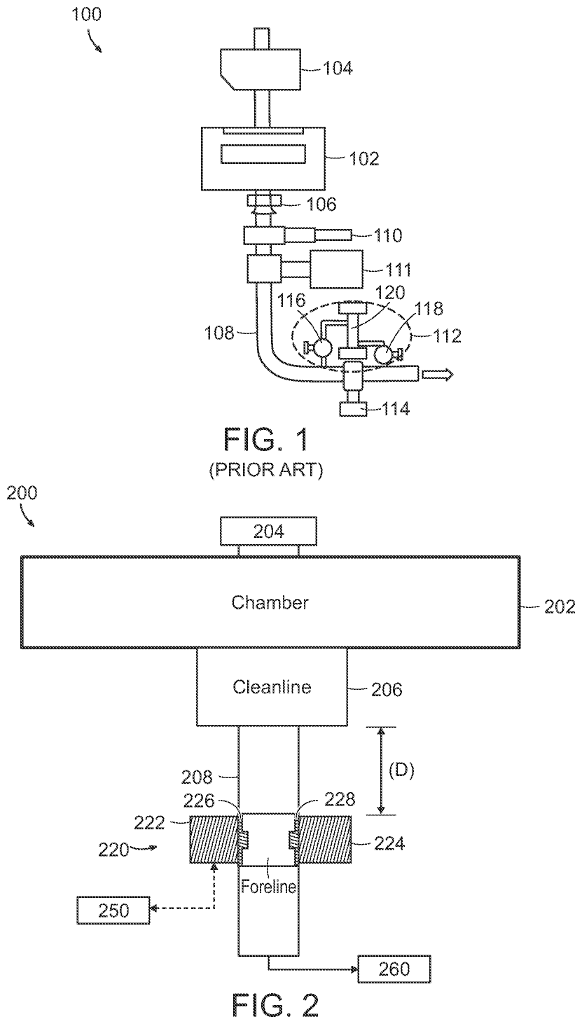

An example of a processing system having a prior-art endpoint detector (EPD) is shown in FIG. 1. The system 100 can be a chemical vapor deposition (CVD) system for a semiconductor processing environment, where the system 100 generally includes a wafer processing chamber 102 configured to process wafers in a deposition process and a vacuum pumping line 108 in fluid connection with the processing chamber 102 and located downstream from the processing chamber 102. Processing chambers may alternatively be referred to herein as deposition chambers. The pumping line 108, which can include a gate valve 110 and a throttle valve 111, can connect the processing chamber 102 to a pump (not shown) of the system 100. The system 100 also includes a chamber cleaning source 104 configured to clean the processing chamber 102 after a deposition operation in the processing chamber 102.

In FIG. 1, the chamber cleaning source 104 is shown to be located upstream and remote from the processing chamber 102. Alternatively, the chamber cleaning source 104 can be another type of cleaning source, such as an integrated source that is incorporated in the processing chamber 102 to clean the chamber 102. The chamber cleaning source 104 can be a plasma source that is configured to generate a reactive gas by applying plasma to a cleaning gas and to introduce the reactive gas to the processing chamber 102 to react with surface films in the chamber 102 for cleaning purposes. From such reaction, a cleaning byproduct is produced, which is alternatively referred to herein as a byproduct signature chemical substance. The cleaning gas supplied to the chamber cleaning source 104 can be, for example, a fluorinated or chlorinated gas (e.g., NF₃, CF₄, NF₃ combined with O₂, SF₆, etc.)

The reactive gas generated from the dissociation of the cleaning gas using plasma can be radical fluorine, which can etch away the unwanted deposits in the chamber surface. The byproduct of such cleaning can be in the form of a signature chemical substance, such as silicon tetrafluoride (SiF₄), which is a stable gas that can be easily removed from the system 100. Alternative chemistry can be employed to achieve cleaning, from which alternative cleaning byproducts can be produced and monitored for the purpose of endpoint detection. For example, in a tungsten deposition system, the byproduct of the cleaning process can be tungsten hexafluoride (WF₆). In other deposition systems, the cleaning gas may contain chlorine, in which case the cleaning byproduct to be monitored may be silicon tetrachloride (SiCl₄).

As illustrated, the system 100 further includes a foreline cleaning source 106 configured to clean at least a section of the vacuum pumping line 108 of the system 100. The foreline cleaning source 106 is coupled to the vacuum pumping line 108 and located downstream from the processing chamber 102, but upstream to the gate valve 110 and the throttle valve 111 of the pumping line 108. As shown in FIG. 1, the foreline cleaning source 106 is configured as an inline plasma source by forming an inline connection with one or more pumping line segments. The plasma source 106 can be substantially the same as the inline plasma source described in U.S. Pat. No. 10,535,506. Such an inline plasma source can generate plasma along the surface of its cylindrical interior volume and use the plasma to dissociate a cleaning gas supplied to the pumping line 108 via an upstream entry point, such as via the processing chamber 102. The resulting reactive gas (e.g., radical fluorine) generated by the foreline cleaning source 106 cleans at least a portion of the pumping line 108, from which a cleaning byproduct, or signature chemical substance, is generated. Alternatively, the foreline cleaning source 106 can be a remote cleaning source and the output of the remote plasma source can be introduced into the pumping line 108 using a tee fitting. In this implementation, an isolation valve may be used between the remote plasma source and the pumping line 108. The cleaning gas used by the foreline cleaning source 106 can be the same as the cleaning gas supplied to the chamber cleaning source 104 (e.g., a fluorinated or chlorinated gas), from which the same reactive gas (e.g., radical fluorine) and cleaning byproduct (e.g., SiF4) are generated during the pumping line cleaning process.

The processing system 100 also includes a downstream endpoint detector 112 coupled to the pumping line 108, where the downstream endpoint detector 112 is located downstream from both the processing chamber 102 and the foreline cleaning source 106. As illustrated, the downstream endpoint detector 112 is mounted onto a bypass on the pumping line 108 such that it is parallel to an optional endpoint bypass valve 114 of the pumping line 108. The endpoint bypass valve 114 can be used to ensure that the gas flow is directed through the downstream endpoint detector 112 to optimize response time. The downstream endpoint detector 112 is configured to monitor a level of the signature chemical substance at its location on the pumping line 108. The signature chemical substance can be generated as a byproduct from a cleaning operation of the processing chamber 102 activated by the chamber cleaning source 104 and/or from a cleaning operation of the pumping line 108 activated by the foreline cleaning source 106, depending on the starting times and durations of these cleaning operations.

The endpoint detector 112 can perform such chemical detection/monitoring in real time or near real time by measuring the partial pressure of the signature chemical substance using infrared absorption. As illustrated in FIG. 1, the endpoint detector 112 includes a pair of isolation valves 116, 118 with a detection cell 120 located therebetween. During a deposition operation, the isolation valves 114, 116 are closed so that no detection occurs. During a cleaning operation activated by the chamber cleaning source 104 and/or the foreline cleaning source 106, the valves 116, 118 are open such that the detection cell 120 can sample the gas flowing through the pumping line 108 at its location and detect a concentration of the signature chemical substance. The endpoint detector 112 is typically configured to scan a slice of spectrum in the infrared region of the gas passing through and produce an absorption spectrum that is used to identify compounds of interest in the gas and provide their concentration values. For instance, the endpoint detector 112 can be a T Series Tunable Filter Spectrometer produced by MKS Instruments, Inc. Alternatively, the endpoint detector 112 can be configured to use other analysis techniques, including non-dispersive infrared (NDIR) analysis, residual gas analyzer (RGA), Fourier transform infrared spectroscopy (FTIR), and/or Optical Emission Spectroscopy (OES) to identify compounds of interest and their concentration values.

The prior-art endpoint detector configuration shown in FIG. 1 can present issues with respect to installation and use in a deposition system as otherwise shown and described. In particular, the endpoint detector 112, which includes an optical sensor, is installed on a bypass line, behind two isolation valves 116, 118, to protect the optical sensor during deposition cycles. A significant amount space may be required to accommodate this bypass line, which may be unavailable in some circumstances. Furthermore, isolation valves may generate particles during use, which may then interfere with operation of the optical sensor and/or other components within the system. Further still, when the optical windows of the endpoint detector degrade, for example, due to a build-up of deposition residue or contaminant particles introduced by other system components, the sensor must typically be removed from the system for cleaning.

The inclusion of an endpoint detector in a bypass line is provided in the above-described system and in other prior-art systems because, without protection from the two isolation valves during a deposition cycle, the optical windows of the detector degrade very quickly, and the sensor can stop functioning in a few wafer batches.

Systems and methods are provided which can overcome the above limitations of prior-art endpoint detection systems. A description of example embodiments follows.

As shown in FIG. 2, a processing system 200 includes a deposition chamber 202 (e.g., a wafer processing chamber), a chamber cleaning source 204, and a foreline cleaning source 206. Elements of the processing system 200 can be similar to those shown and described with respect to system 100 and FIG. 1, except where otherwise provided. The chamber cleaning source 204 and foreline cleaning source 206 are configured to provide a cleaning agent (e.g., a reactive gas) to, respectively, the chamber 202 and foreline 208. The cleaning agent provided by each of the cleaning sources 204, 206 is typically a same reactive gas (e.g., NF₃) to provide for cleaning of a same product deposited within the chamber and foreline (e.g., SiO₂); however, the cleaning agents may optionally differ. Where the cleaning agent provided by each of the cleaning sources 204, 206 is a same reactive gas, a same cleaning byproduct (e.g., SiF₄) is produced by the chamber and foreline cleaning processes.

The processing system 200 includes an endpoint detector (EPD) 220 disposed in the foreline (i.e., not within a bypass of the foreline). The EPD can be or include an optical sensor to provide for detection of the cleaning byproduct. As illustrated in FIG. 2, the optical windows 226, 228 of the EPD are disposed at an inner surface of the foreline 208. The optical windows can be formed of one or more materials that are stable when exposed to free radicals involved in the cleaning process. For example, the windows can be formed of CaF₂ and BaF₂, which are stable when exposed to F⁻ radicals.

The optical windows can be opposingly disposed within the foreline to provide for transmission of an optical signal from an optical source 222 to an optical detector 224. The optical detector 224 can optionally be a detector array. The EPD can provide for detection of the cleaning byproduct through any suitable optical analysis technique, including, for example, filter spectroscopy, non-dispersive infrared (NDIR) analysis, residual gas analysis (RGA), Fourier transform infrared spectroscopy (FTIR), and/or Optical Emission Spectroscopy (OES) to identify compounds of interest and their concentration values.

As further illustrated in FIG. 2, the EPD 220 is disposed in the foreline 208 at some distance (D) downstream from the foreline cleaning source 206. During a deposition process, the windows 226, 228 of the detector will typically become fouled with the deposited product, thereby compromising optical transmission through the windows. During a foreline cleaning process using the system 200, material deposited on the windows 226, 228 during the deposition cycle is removed, thereby providing for transmission recovery through the EPD. Electronics 250 of the EPD can provide for the monitoring of transmission recovery of the optical sensor during the cleaning process, and determination of at least one of a foreline clean endpoint and a chamber clean endpoint can be based, at least in part, on the monitored recovery.

In particular, where the foreline cleaning source 206 and EPD 220 are installed inline, a distance (D) between the foreline cleaning source 206 and EPD 220 can dictate a rate of transmission recovery during a cleaning process. Depending upon the distance (D), different methods of determining chamber and/or foreline clean endpoints can be employed, each of which is described in turn.

Where the EPD 220 is installed relatively close to the foreline cleaning source 206, activation of the foreline cleaning source can result in a transmission level of the optical sensor reaching a threshold recovery value within a short period of time. Thereafter, the optical sensor can be used to monitor a concentration of the cleaning byproduct present in the foreline, which can provide for an accurate measurement of a cleaning status of the chamber 202.

In particular, where the EPD 220 is installed close to the foreline cleaning source 206 (e.g., less than about 50 cm, or less than about 1 m), material deposited on the optical windows 226, 228 can be quickly cleaned, and the EPD can then be used to provide for a more consistent and more accurate chamber clean measurement, due to a more consistent optical signal, than that provided by endpoint detection systems in which an optical sensor is disposed in a bypass line.

An example cleaning paradigm and EPD response is shown in FIG. 4. As illustrated, activation of a chamber cleaning process (line C) and foreline cleaning process (line D) occurs substantially concurrently. A cleaning byproduct (e.g., SiF₄) concentration (line A), as measured by the EPD, is initially a convolved representation of cleaning byproduct from both the chamber cleaning and foreline cleaning processes. When the EPD is disposed adjacent to or a short distance downstream of the foreline cleaning source, the optical windows of the sensor can be cleaned within a short period of time after the start of the cleaning process. Infrared transmission through the sensor (line B) can be restored to its original or intended level (e.g. as before the deposition cycle), as indicated by reaching a target transmission threshold (line E). Restoration of transmission through the sensor to the target threshold can occur relatively soon after the cleaning process is initiated and before the chamber cleaning process is complete. The transmission level reaching a target threshold can thereby indicate that the foreline upstream of the EPD is clean, and SiF₄ measurements obtained after this point can be indicative of the status of chamber cleaning. A chamber clean endpoint can be reported when the SiF₄ signal drops to a target threshold (line F). Because the measurement of SiF₄ is obtained during a period of time in which the windows have been determined to be fully or substantially cleaned, improved accuracy and consistency with respect to the detection of chamber clean endpoints can be obtained. Optionally, with respect to a foreline clean endpoint, a margin of time can be added after detection of a suitable transmission recovery level before the foreline cleaning process is terminated to provide for cleaning of the foreline downstream of the EPD.

Alternatively, the EPD can be installed at some greater distance downstream of the foreline cleaning source (e.g., greater than about 1 m, greater than about 2 m, or about 1 m to about 15 m). The distance can be such that a chamber clean endpoint is reached before a foreline clean endpoint. In such a configuration, the efficiency of window cleaning by the foreline cleaning source is reduced. However, a measured level of transmission through the optical windows can better represent the cleanliness of the foreline. Advantageously, if there is a system component of interest 260 for which it is desirable to ensure that adequate cleaning has been obtained (e.g., for a dry pump), the EPD can be installed adjacent to the component to provide for a more accurate indication of the cleanliness of the foreline at that location.

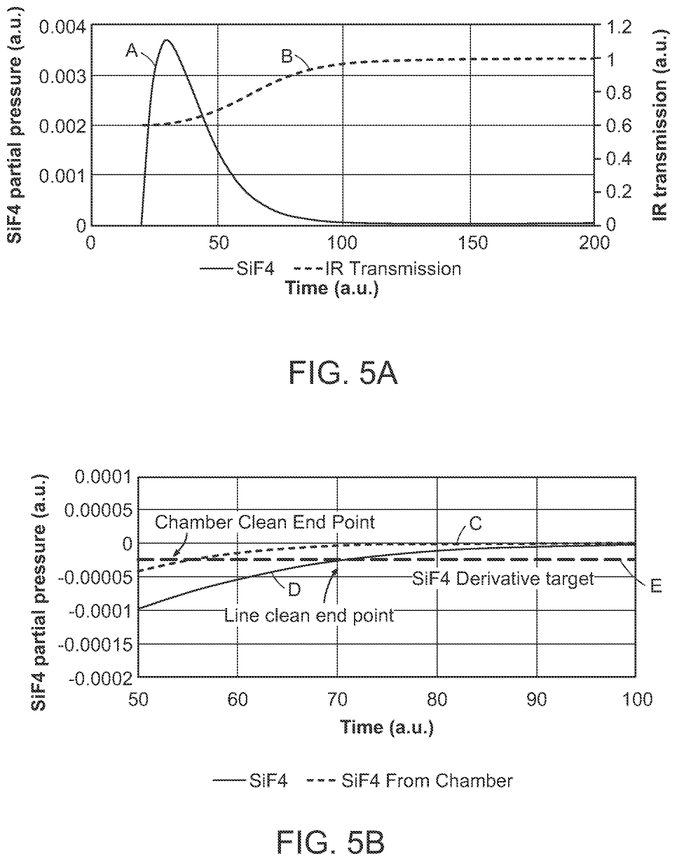

An example cleaning paradigm and EPD response is shown in FIGS. 5A-B. As illustrated therein, a transmission recovery rate of the EPD (line B) is significantly slower than that illustrated in FIG. 4. In this case, a chamber clean endpoint, as indicated by a concentration of cleaning product (line A) being reduced to a suitable level, can be reached before transmission through the EPD has fully recovered. To provide for the determination of a chamber clean end point with such a configuration, the EPD and the foreline cleaning source can be calibrated prior to operation. The calibration can provide for a mapping of transmission recovery rate to a derivative signal of the measured cleaning byproduct concentration.

During a cleaning operation, a concentration, or a change in concentration, of the cleaning byproduct emanating from the chamber cleaning process can be calculated based on the measurement of the transmission recovery rate and the calibration. The short-dashed line (line C, FIG. 5B) shows an example calculated chamber clean derivative curve, which, as illustrated, reaches a target threshold (line E, FIG. 5B) first (i.e., indicating that a chamber clean endpoint has been reached). When the SiF₄ signal subsequently reaches a threshold value, or its derivative (line D, FIG. 5B) reaches a derivate threshold, a foreline cleaning endpoint is indicated. As illustrated, the derivate threshold (line E) for both the chamber and foreline clean endpoints is a same threshold (line E); however, different threshold values can apply. With this method, a foreline clean endpoint can be more accurately measured.

Transmission recovery in the system 200 can be monitored with use of an optical signal having a wavelength that is not absorbed by a cleaning byproduct generated during the cleaning process. The cleaning byproduct concentration can be measured with use of an optical signal having a wavelength at which absorption with the cleaning byproduct occurs.

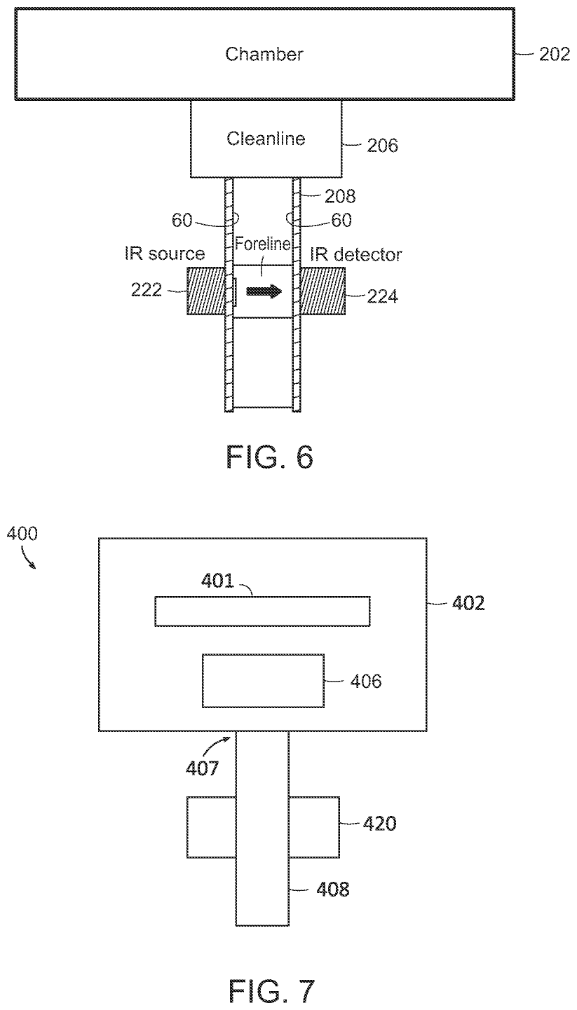

As further illustrated in FIG. 6, upon completion of a deposition cycle, a coating 60 of deposited material (e.g., Si-based particles) in the foreline 208 attenuates transmission of light from an optical source to an optical detector of the EPD. As the line is being cleaned, the coating 60 can become thinner and eventually disappear. For example, where the coating comprises Si-based particles, the particles are converted into SiF₄ upon exposure to the reactive gas, and the resulting cleaning byproduct of SiF₄ gas is evacuated from the line. A rate of improvement in transmission through the EPD can be mathematically related (e.g., linearly related) to the SiF₄ generated by the line cleaning process. A calibration process can be performed to determine such a relationship.

The following example calibration process is described with respect to an example use case in which the deposited material comprises Si-particles and the monitoring of a cleaning byproduct involves the monitoring of an SiF₄ signal in the infrared (IR) range; however, a similar calibration process can be applied where the coating material, cleaning byproduct, and/or optical range differ.

The thickness (T) of an Si-coating in the foreline can be defined as follows, where a is a coefficient, P is a measured transmission power, and P₀ is a transmission power without a deposit layer:

$$T = a ( 1 - \frac{P}{{P}_{0}} ) \qquad ( 1 )$$

The coefficient a can depend on a particle type of which the coating is comprised. The SiF₄ signal obtained during a line clean (Sₗᵢₙₑ) can be defined as follows, where b is a coefficient and T′ is the time derivative of the thickness of the Si-layer:

Sₗᵢₙₑ=b×T′ (2)

The coefficient b can depend on geometric parameters of the line (e.g., area, etc.). Accordingly, the SiF₄ signal can redefined as follows:

$${S}_{line} = - \frac{ab}{{P}_{0}} {P}^{′} \qquad ( 3 )$$

Near a cleaning endpoint, a measured transmission power can be defined as follows, where c and d are scaling coefficients and t is time:

P≅c(1−e^{-d·t}) (4)

Accordingly, a rate of change of the measured transmission power can be defined as follows:

P′=cde^{-d·t}=−d·P+cd (5)

Eqn. 4 provides for an example equation that estimates transmission power of a sensor near an endpoint of a cleaning process. Other equations may alternatively be used to estimate or model transmission over time. Furthermore, with Eqn. 5, the SiF₄ signal can thereby be alternatively defined as follows:

$${S}_{line} = - \frac{ab}{{P}_{0}} {P}^{′} = - \frac{ab}{{P}_{0}} ( ( - d \cdot P + cd ) ) = abd ( \frac{P}{{P}_{0}} ) + ( - \frac{abcd}{{P}_{0}} ) \qquad ( 6 )$$

Simplifying, where C₁ and C₀ are coefficients depending on a, b, c, d, and P₀:

Sₗᵢₙₑ=C1·P/P₀+C₀ (7)

As such, a signal indicative of an SiF₄ concentration in the foreline can be determined based on a measured and calibrated transmission through the EPD. Furthermore, a time derivative of Sₗᵢₙₑ can be defined as follows, where C₂ is another calibration coefficient.

$${S}_{line}^{′} = {C}_{2} \cdot {( \frac{P}{{P}_{0}} )}^{2} + {C}_{1} \cdot \frac{P}{{P}_{0}} + {C}_{0} \qquad ( 8 )$$

Accordingly, with determination of C₀, C₁, and C₂, a mapping or modeling of a relationship between IR transmission through the sensor and a corresponding line clean SiF₄ signal can be provided.

As illustrated in FIG. 5A, a measured SiF₄ signal (line A) can be a convolved representation of cleaning byproduct from both the chamber cleaning and foreline cleaning processes. The measured transmission curve (line B) can be used to provide for S′ₗᵢₙₑ, as described above and given known calibration coefficients C₀, C₁, and C₂. As further shown in FIG. 5B, from the measured, convoluted SiF4 signal, which includes the cleaning byproducts from both the chamber and line, a derivative of the convoluted SiF₄ signal (line D) can be obtained. Further, a curve for S′ₗᵢₙₑ can be obtained from the measured transmission curve. An S′_{chamber} curve (line C) can thereby be obtained from subtraction of S′ₗᵢₙₑ from the derivative of the convoluted SiF₄ curve (line D), from which a chamber clean end point can be determined. Alternatively, or in addition, the SiF₄ signal can be used to obtain an endpoint instead of the derivative in situations in which a magnitude of S_{chamber} is significantly greater than Sₗᵢₙₑ.

If an approximation according to Eqn. 4, above, is insufficient, a higher order polynomial can be used for the modeling.

To calibrate an EPD, a section of the foreline that includes the EPD sensor windows can be pre-coated with a deposit material. The chamber and/or foreline cleaning sources can then be activated, and both the transmission curve and the SiF₄ curve can be recorded throughout the cleaning process. The coefficients C₀, C₁, and C₂ can be determined and, optionally, the coefficients can be validated with an independent run. With a fixed foreline size and a fixed flow rate, such a calibration can be held throughout a lifetime of the system.

A distance (D) between the foreline cleaning source and the EPD 220 can be selected to provide for a targeted rate of transmission recovery, depending upon measurement objectives. Optionally, two or more EPDs can be included in a system. For example, one EPD can be included at a location that is relatively close to the foreline cleaning source, and another EPD can be included at a location farther downstream and closer to a component of interest, such as a pump.

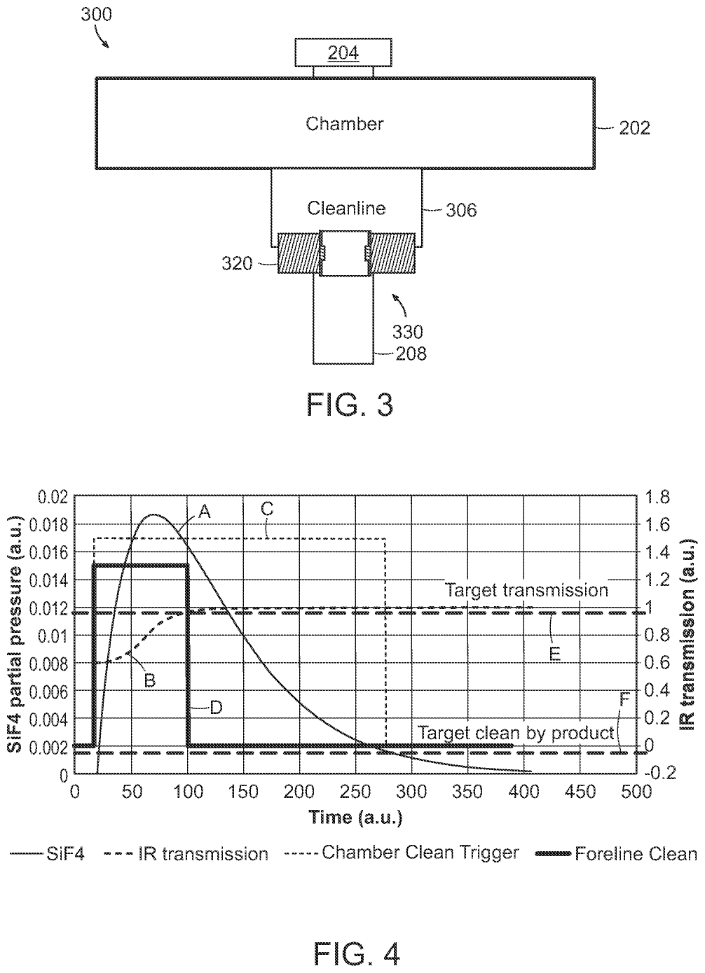

As illustrated in FIG. 3, a system 300 can include an EPD 320 that is disposed at or in an outlet 330 of the foreline cleaning source 306. Optionally, the EPD 320 can be integral with the foreline cleaning source 306.

EPDs as shown and described herein can also provide for an indication of cleanliness or dirtiness of the foreline of a system. In particular, a measured transmission level of an EPD can represent the dirtiness of the foreline at a particular location (e.g., near a critical component), and, based on the measured transmission level, a determination as to whether to run or not run a line cleaning process can be made. For example, a line cleaning process may not have to be run for every chamber cleaning cycle, and an indication of cleanliness of the foreline at a particular location can be informative as to whether a cleaning process should be run.

A transmission level can be measured by the detector with a signal in a wavelength band at which there is no absorption of the cleaning byproduct (e.g., SiF₄). A detector of the optical sensor can be placed at a focus point of the collection optics of the sensor. A detected drop in a transmission signal can be due to attenuation due to the thickness of the deposit film and/or can be due to scattering from powder that has attached to the surface of the windows. Optionally, a detector of the optical sensor can be a detector array, and a ratio between the power collected by a detector element that is placed at the focus of the optics and the other detector element(s) can provide an indication of a level of scattering. Attenuation and/or scattering measurements can be used for an indication of cleanliness of the foreline.

The provided methods and systems offer several advantages over prior-art endpoint detection methods and systems. In particular, bypass and isolation valves can be omitted from the system, physical space can be saved, and installation of the system can be significantly easier than that of prior-art systems. Furthermore, the EPD can provide for accurate measurement of both a chamber clean endpoint and a foreline clean endpoint, and can be placed at varying distances from the foreline cleaning source, providing for flexibility with installation and tailoring to specific measurement objectives.

In some systems, it may be required that a flow rate in the foreline may maintained a high level during a chamber cleaning process. In such cases, a very low pressure drop can occur across a bypass line, which makes flow in the bypass line much slower than that in the main line. Therefore, a chamber clean endpoint captured by a sensor installed in the bypass line can be significantly delayed. Installation of an EPD directly on the foreline can advantageously avoid endpoint measurement errors in such cases.

Additionally, isolation valves on a bypass line have been known to create extra particles. The omission of isolation valves for a bypass line for an EPD sensor can advantageously avoid such problems.

Optical window contamination is a common problem for IR-based endpoint detection. With installation downstream of inline foreline cleaning source, such as that described in U.S. Pat. No. 10,535,506, the entire teachings of which are incorporated herein by reference, the windows of an IR-based endpoint detector can be maintained in a state that provides for high transmission, which can improve the consistency and accuracy of chamber clean endpoint measurements.

When used to monitor a light intensively level, an IR-based EPD disposed on or in the foreline can further function as an indicator of an accumulation level of deposit material in the foreline. When a measured intensity level is low, the EPD can provide for an indication that the line should be cleaned. An increase in light intensity, as measured during or after a cleaning process, can provide for an indication of cleaning endpoint(s). Thus, such EPD configurations can provide for multiple functions within the system.

While the configurations shown in FIGS. 2 and 3 illustrate foreline cleaning sources 206, 306 disposed downstream of or at an outlet of a chamber 202, a foreline cleaning source can alternatively be provided within the chamber. For example, as shown in FIG. 7, a processing system 400 can include elements similar to those shown and described in FIGS. 1, 2, and 3, but have a chamber 402 that includes a foreline cleaning source 406. The foreline cleaning source 406 can be disposed at a lower region of an interior of the chamber 402, below a wafer pedestal 401 and near an entrance 407 of the foreline 408. The foreline cleaning source can, for example, be disposed above the bottom interior surface of the chamber, as illustrated in FIG. 7.

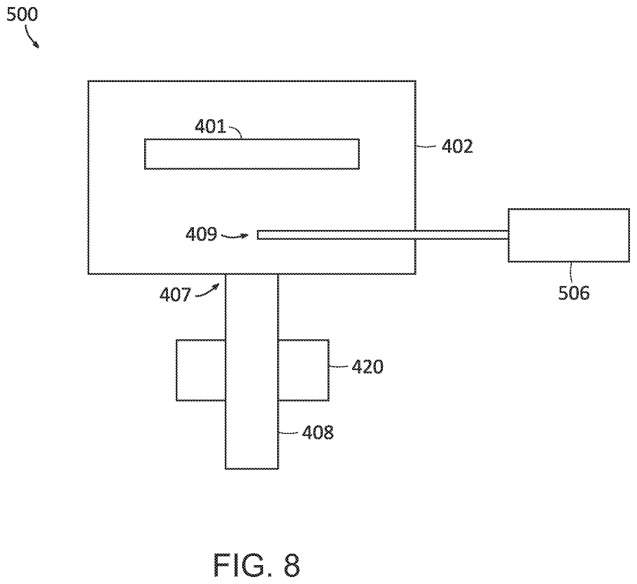

Alternatively, a system 500 can include a remote plasma source 506 in fluid communication with an interior region of the chamber 402 at a lower portion 409 thereof. The systems 400, 500 can include an EPD 420, as further described with respect to FIGS. 2 and 3. In the configurations shown in FIGS. 7 and 8, the in-chamber foreline cleaning source 406 or remote plasma source 506 can be configured to dissociate cleaning gas within the lower region of the chamber 402 (e.g., which may be present as a result of recombination of the reactive gas introduced from above) so that the resulting reactive gas can be conveyed into the foreline 408.

The teachings of all patents, published applications and references cited herein are incorporated by reference in their entirety.

While example embodiments have been particularly shown and described, it will be understood by those skilled in the art that various changes in form and details may be made therein without departing from the scope of the embodiments encompassed by the appended claims.

What is claimed is:

1. A method of monitoring a cleaning process for a deposition chamber, comprising:
activating a chamber cleaning source to supply a cleaning agent to a deposition chamber;
activating a foreline cleaning source disposed downstream of the deposition chamber to supply the cleaning agent to a foreline;
monitoring transmission recovery of an optical sensor disposed in the foreline at a location downstream of the foreline cleaning source; and
detecting at least one of a foreline clean endpoint and a chamber clean endpoint based on the monitored transmission recovery.

2. The method of claim 1, wherein the foreline clean endpoint is detected based on a transmission level of the optical sensor reaching a threshold recovery value and wherein the method further comprises monitoring a concentration of a cleaning byproduct in the foreline with the sensor.

3. The method of claim 2, wherein the chamber clean endpoint is detected based on the monitored concentration of the cleaning byproduct reaching a threshold value.

4. The method of claim 2, wherein monitoring the concentration of the cleaning byproduct is based on at least one of tunable filter spectroscopy (TFS), non-dispersive infrared (NDIR) analysis, residual gas analysis (RGA), Fourier transform infrared spectroscopy (FTIR), and optical emission spectroscopy (OES).

5. The method of claim 1, wherein the chamber clean endpoint is detected based on a transmission recovery rate and a rate of change of a monitored concentration of the cleaning product by the sensor, the transmission recovery rate being calibrated to a rate of change of concentration of a cleaning byproduct in the foreline.

6. The method of claim 5, wherein the chamber clean endpoint is detected based on a difference between the transmission recovery rate and the rate of change of the monitored concentration of cleaning byproduct reaching a threshold value.

7. The method of claim 1, wherein the foreline clean endpoint is detected based on a transmission recovery rate reaching a threshold value, the transmission recovery rate being calibrated to a rate of change of concentration of a cleaning byproduct in the foreline.

8. The method of claim 1, wherein monitoring transmission recovery of the optical sensor comprises monitoring an optical signal having a wavelength not absorbed by a cleaning byproduct generated during cleaning with the cleaning agent.

9. The method of claim 1, further comprising monitoring an optical signal having a wavelength absorbed by the cleaning byproduct.

10. The method of claim 9, further comprising determining a concentration of a cleaning byproduct present in at least one of the foreline and the chamber based on the monitored transmission recovery and the monitored optical signal having the wavelength absorbed by the cleaning byproduct.

11. The method of claim 1, wherein activating the foreline cleaning source occurs concurrently with activating the chamber cleaning source.

12. The method of claim 1, wherein the optical sensor comprises optical windows disposed at an inner surface of the foreline.

13. The method of claim 1, wherein a spacing between the foreline cleaning source and the optical sensor is selected to provide for a targeted rate of transmission recovery.

14. The method of claim 1, wherein a spacing between the foreline cleaning source and the optical sensor is selected to provide for detection of the foreline clean endpoint at a location in the foreline associated with a deposition system component located downstream of the deposition chamber.

15. The method of claim 14, wherein the deposition system component is a pump.

16. The method of claim 1, wherein the optical sensor is disposed at an outlet of the foreline cleaning source.

17. The method of claim 1, wherein the cleaning byproduct is a fluorinated, chlorinated, or oxygen-containing gas formed from reaction of the cleaning agent with a deposition material.

18. The method of claim 17, wherein the cleaning byproduct is SiF₄.

19. A system for monitoring cleaning of a deposition chamber, comprising:
a chamber cleaning source configured to supply a cleaning agent to a deposition chamber;
a foreline cleaning source disposed downstream of the deposition chamber and configured to supply the cleaning agent to a foreline;
an optical sensor disposed in the foreline at a location downstream of the foreline cleaning source; and
electronics configured to monitor transmission recovery of the optical source and detect at least one of a foreline clean endpoint and a chamber clean endpoint based on the monitored transmission recovery.

20. The system of claim 19, wherein the electronics are configured to detect the foreline clean endpoint based on a transmission level of the optical sensor reaching a threshold recovery value.

21. The system of claim 20, wherein the optical sensor is disposed in the foreline at a distance of less than about 50 cm, or less than about 1 m, downstream from the foreline cleaning source.

22. The system of claim 19, wherein the electronics are further configured to monitor a concentration of a cleaning byproduct in the foreline with the sensor.

23. The system of claim 19, wherein the electronics are configured to detect the chamber clean endpoint based on a transmission recovery rate and a rate of change of a monitored concentration of the cleaning byproduct by the sensor, the transmission recovery rate being calibrated to a rate of change of concentration of a cleaning byproduct in the foreline.

24. The system of claim 23, wherein the optical sensor is disposed in the foreline at a distance of greater than about 1 m, or greater than about 2 m, downstream from the foreline cleaning source.

25. The system of claim 19, wherein the electronics are configured to detect the chamber clean endpoint based on a difference between the transmission recovery rate and the rate of change of the monitored concentration of cleaning byproduct reaching a threshold value.

26. The system of claim 19, wherein the electronics are configured to detect the foreline clean endpoint based on a transmission recovery rate reaching a threshold value, the transmission recovery rate being calibrated to a rate of change of concentration of a cleaning byproduct in the foreline.

27. The system of claim 19, wherein the optical sensor comprises optical windows disposed at an inner surface of the foreline.

28. The system of claim 19, wherein the optical sensor is disposed at an outlet of the foreline cleaning source.

29. The system of claim 28, wherein the optical sensor is integral with the outlet of the foreline cleaning source.

30. A method for monitoring cleanliness of a foreline in a deposition system, comprising:
with an optical sensor disposed in a foreline at a location downstream of a deposition chamber, measuring transmission of an optical signal through the foreline, the measured transmission indicative of an amount of deposited material present in the foreline.

31. The method of claim 30, wherein the optical sensor comprises optical windows disposed at an inner surface of the foreline.

32. The method of claim 31, wherein measuring transmission through the foreline comprises measuring attenuation of the optical signal, the measured attenuation indicative of a thickness of a film of the deposited material at an inner surface of the foreline.

33. The method of claim 32, wherein the optical sensor comprises a detector array, and wherein measuring transmission through the foreline comprises measuring scattering of the optical signal.

34. The method of claim 30, further comprising monitoring a concentration of a cleaning byproduct in the foreline with the optical sensor.
